(19) United States
(12) Patent Application Publication
(10) Pub. No.: US 2023/0073010 A1
(43) Pub. Date: Mar. 9, 2023

(54) METHOD FOR MASS TRANSFER, LED DISPLAY DEVICE, AND DISPLAY APPARATUS

(71) Applicant: CHONGQING KONKA PHOTOELECTRIC TECHNOLOGY RESEARCH INSTITUTE CO., LTD., Chongqing (CN)

(72) Inventors: Feng ZHAI, Chongqing (CN); CHUN-LUNG HSIAO, Chongqing (CN)

(21) Appl. No.: 17/986,363

(22) Filed: Nov. 14, 2022

Related U.S. Application Data
(63) Continuation of application No. PCT/CN2021/110395, filed on Aug. 3, 2021.

(51) Int. Cl. H01L 21/683; H01L 25/075; H01L 33/00; H01L 33/62

(52) U.S. Cl. CPC H01L 21/6835; H01L 25/0753; H01L 33/0093; H01L 33/0095; H01L 33/62; H01L 2933/0066; H01L 2221/68309; H01L 2221/68354; H01L 2221/68363

(57) ABSTRACT

A method for mass transfer, a light-emitting diode (LED) display device, and a display apparatus are provided. The method includes: applying an insulating-adhesive on a growth substrate, where the insulating-adhesive applied is between two adjacent LED chips; placing the growth substrate above a display backplane, where a distance between the growth substrate and the display backplane after placing is greater than a height of an LED chip; forming an insulating-adhesive column between the growth substrate and the display backplane by softening the insulating-adhesive through heating, where the softened insulating-adhesive subjected to heating is adhered to the display backplane; separating the LED chip from the growth substrate, to make the separated LED chip fall onto a corresponding pad-group through a channel formed by insulating-adhesive columns around the separated LED chip; and bonding the fallen LED chip with the corresponding pad-group on the display backplane.

This application is a continuation of International Application No. PCT/CN2021/110395, filed Aug. 3, 2021, the disclosure of which is hereby incorporated by reference in its entirety.

### TECHNICAL FIELD

This application relates to the field of mass transfer technology, and particularly to a method for mass transfer, a light-emitting diode (LED) display device, and a display apparatus.

### BACKGROUND

At present, since a micro light-emitting diode (“micro LED” for short) display, as a new generation of display technology, has advantages of high brightness, good luminous efficiency, and low power consumption, etc., micro LEDs have been widely used.

The micro LED display generally includes multiple pixel areas, and each of the pixel areas includes a red LED chip, a blue LED chip, and a green LED chip. During display manufacturing, three types of chips need to be transferred from their respective growth substrates to a display backplane. The existing transfer method, however, requires many materials and has a high cost and a cumbersome process. Moreover, the entire process needs to transfer LED chips multiple times, which can easily cause the LED chip to fail to align with a pad-group on the display backplane. As a result, it is difficult to guarantee a welding strength of the LED chip, which may lead to abnormal connection between the LED chip and a drive circuit, or even falling of the LED chip from the display backplane.

### SUMMARY

A first aspect of the disclosure provides a method for mass transfer. The method includes the following. An insulating-adhesive is applied on a growth substrate, where the insulating-adhesive applied is between any two adjacent light-emitting diode (LED) chips on the growth substrate. The growth substrate is placed above a display backplane, where a distance between the growth substrate and the display backplane after placing is greater than a height of an LED chip. An insulating-adhesive column is formed between the growth substrate and the display backplane by softening the insulating-adhesive through heating, where the softened insulating-adhesive subjected to heating is adhered to the display backplane. An LED chip is separated from the growth substrate, to make the separated LED chip fall onto a corresponding pad-group through a channel formed by insulating-adhesive columns around the separated LED chip. The fallen LED chip is bonded with the corresponding pad-group on the display backplane.

A second aspect of the disclosure provides an LED display device. The LED display device includes a display backplane and multiple LED chips. The multiple LED chips are transferred to the display backplane by the method for mass transfer described in the first aspect of the disclosure.

A third aspect of the disclosure provides a display apparatus. The display apparatus includes a drive circuit and the LED display device described in the second aspect of the disclosure. The LED display device is electrically connected to the drive circuit.

### BRIEF DESCRIPTION OF THE DRAWINGS

FIG. 1 is a schematic structural diagram illustrating a growth substrate provided in the related art.

FIG. 2 is a schematic structural diagram illustrating a growth substrate from another perspective provided in the related art.

FIG. 3 is a schematic structural diagram illustrating that a temporary substrate is adhered to a growth substrate provided in the related art.

FIG. 4 is a schematic structural diagram illustrating a process of transferring light-emitting diode (LED) chips on a growth substrate to a temporary substrate provided in the related art.

FIG. 5 is a schematic structural diagram illustrating a temporary substrate with LED chips transferred thereon provided in the related art.

FIG. 6 is a schematic structural diagram illustrating a temporary substrate with LED chips transferred thereon from another perspective provided in the related art.

FIG. 7 is a schematic structural diagram illustrating a process of transferring of LED chips on a temporary substrate to a transfer substrate provided in the related art.

FIG. 8 is a schematic structural diagram illustrating a display backplane with LED chips transferred thereon provided in the related art.

FIG. 9 is a schematic flowchart illustrating a method for mass transfer provided in implementations of the disclosure.

FIG. 10 to FIG. 13 are schematic diagrams illustrating processes of a method for mass transfer provided in implementations of the disclosure.

FIG. 14 is a schematic diagram illustrating a specific flow of a process illustrated in FIG. 13.

FIG. 15 is a schematic flowchart illustrating a method for mass transfer provided in other implementations of the disclosure.

FIG. 16 to FIG. 20 are schematic diagrams illustrating processes of a method for mass transfer provided in other implementations of the disclosure.

FIG. 21 is a schematic flowchart illustrating a method for mass transfer provided in other implementations of the disclosure.

FIG. 22 is a schematic diagram illustrating a process of the operation S350 in FIG. 21.

FIG. 23 is a schematic diagram illustrating a characteristic of insulating-adhesive provided in implementations of the disclosure.

FIG. 24 is a schematic structural diagram illustrating a first groove on a growth substrate provided in implementations of the disclosure.

FIG. 25 is a schematic structural diagram illustrating a second groove on a display backplane provided in implementations of the disclosure.

FIG. 26 is a schematic structural diagram illustrating an LED display device provided in implementations of the disclosure.

Description of reference signs: 10—growth substrate, 11—first groove, 20—LED chip, 20a—defective LED chip, 30—temporary substrate, 40—transfer substrate, 50—display backplane, 51—pad-group, 52—second groove, 60—insulating-adhesive, 61—first bottom edge, 62—second bottom edge, 70—insulating-adhesive column, 71—third bottom edge, 72—fourth bottom edge, 80—sticky repair board.

### DETAILED DESCRIPTION

In order to facilitate understanding of the disclosure, the disclosure will be described fully below with reference to accompanying drawings. The accompanying drawings illustrate exemplary implementations of the disclosure. However, the disclosure may be implemented in many different forms and is not limited to the implementations described herein. Rather, these implementations are provided to achieve a thorough and complete understanding of disclosed contents of the disclosure.

Unless otherwise defined, all technical and scientific terms herein have the same meaning as commonly understood by one of ordinary skill in the technical field to which the disclosure belongs. The terms herein are merely for the purpose of describing implementations of the disclosure, which are not intended to limit the disclosure.

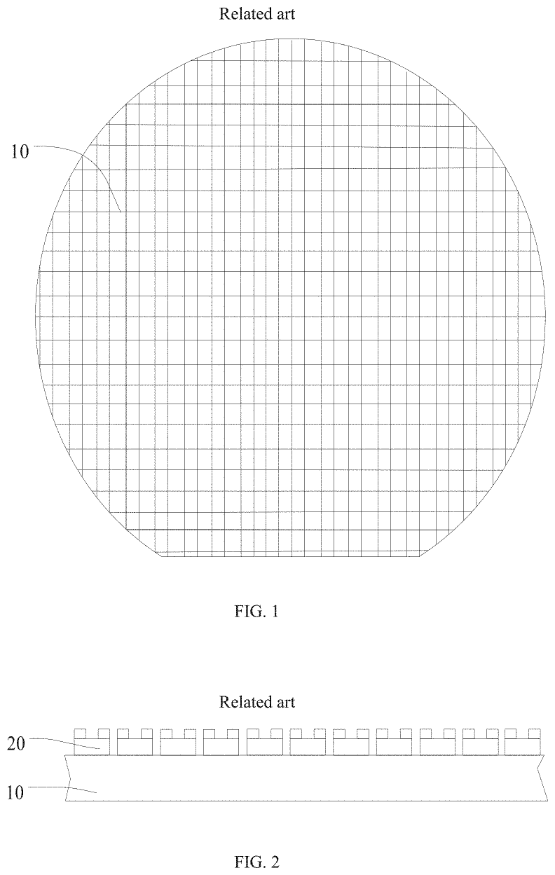

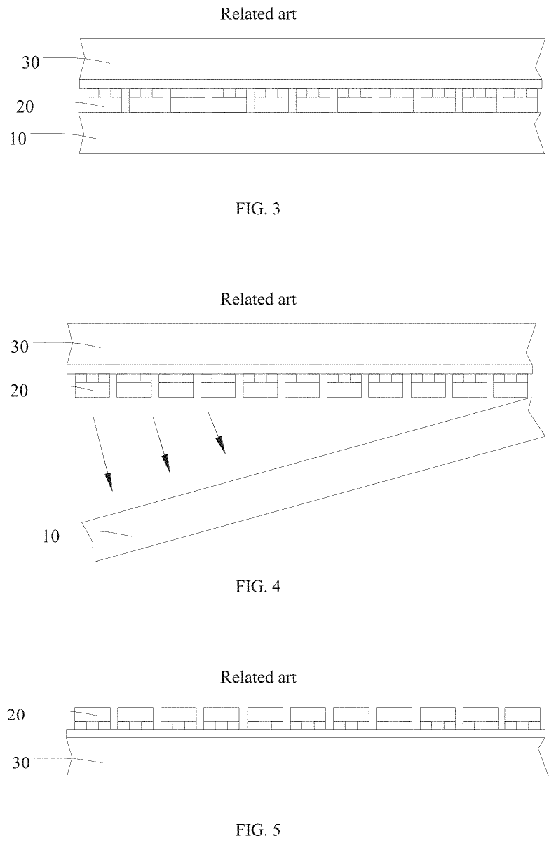

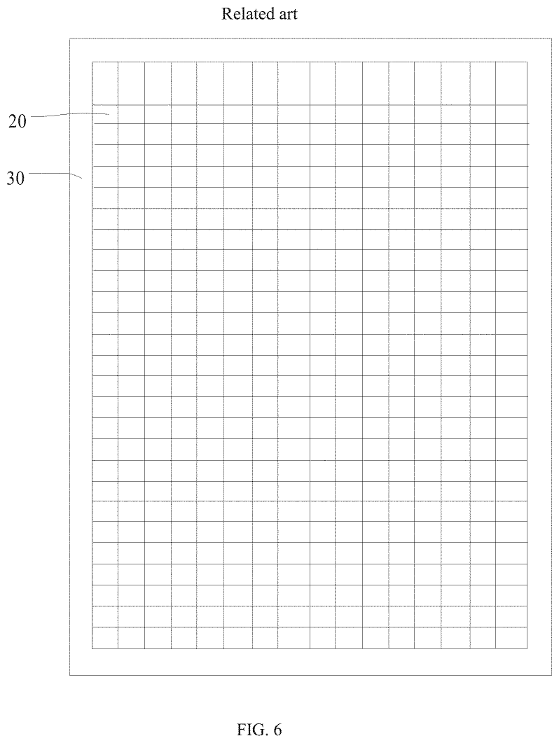

Referring to FIG. 1 to FIG. 6, FIG. 1 is a schematic structural diagram illustrating a growth substrate provided in implementations of the disclosure. FIG. 2 is a schematic structural diagram illustrating a growth substrate from another perspective provided in implementations of the disclosure. FIG. 3 is a schematic structural diagram illustrating that a temporary substrate is adhered to a growth substrate provided in implementations of the disclosure. FIG. 4 is a schematic structural diagram illustrating a process of transferring light-emitting diode (LED) chips on a growth substrate to a temporary substrate provided in implementations of the disclosure. FIG. 5 is a schematic structural diagram illustrating a temporary substrate with LED chips transferred thereon provided in implementations of the disclosure. FIG. 6 is a schematic structural diagram illustrating a temporary substrate with LED chips transferred thereon from another perspective provided in implementations of the disclosure.

Generally, when transferring LED chips 20 to a display backplane 50, red LED chips, blue LED chips, and green LED chips are transferred respectively. In the following, one type of LED chips 20 is taken as an example for description, and the other two types of LED chips are transferred in the same manner, which will not be repeated in the disclosure. LED chips 20 are transferred to the display backplane 50 as follows.

At S10, a growth substrate 10 (e.g., a wafer) on which LED chips 20 are grown is provided. Then, the LED chips 20 are adhered to a temporary substrate 30 through an adhesive layer on the temporary substrate 30. Next, the growth substrate 10 is stripped off from the LED chips 20. In this way, the LED chips 20 can be transferred onto the temporary substrate 30.

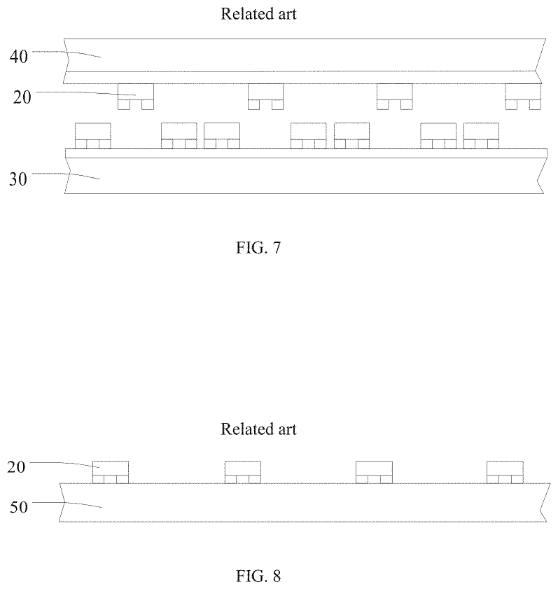

At S11, the LED chips 20 are selectively adhered to a transfer substrate 40 through an adhesive layer on the transfer substrate 40. Referring to FIG. 7, FIG. 7 illustrates that LED chips 20 on the temporary substrate 30 are selectively adhered to the transfer substrate 40.

At S12, LED chips 20 on the transfer substrate 40 are transferred onto the display backplane 50. Referring to FIG. 8, FIG. 8 is a schematic diagram illustrating a display backplane 50 with LED chips 20 transferred thereon. In a process of transferring the LED chips 20 on the transfer substrate 40 onto the display backplane 50, mass welding is performed. Therefore, after the transferring is completed, gold-indium eutectic bonding for the LED chip 20 has been completed.

In a mass transfer process, stickiness of the adhesive layer on the temporary substrate needs to be smaller than stickiness of the adhesive layer on the transfer substrate, and thus, the transfer process requires many materials and has a high cost. Moreover, the entire process includes a process from the growth substrate to the temporary substrate, a process from the temporary substrate to the transfer substrate, and a process from the transfer substrate to the display backplane. As can be seen, the entire process is cumbersome, and LED chips need to be transferred multiple times, which may easily lead to the LED chip to fail to align with a pad-group on the display backplane. As a result, it is difficult to guarantee a welding strength of the LED chip, which may lead to abnormal connection between the LED chip and a drive circuit, or even falling of the LED chip from the display backplane.

In view of the above deficiencies, the disclosure provides a method for mass transfer, an LED display device, and a display apparatus, which aims to solve problems of abnormal connection between an LED chip and a drive circuit or even falling of the LED chip from a display backplane, where these problems are caused by a low welding strength of the LED chip due to inability of the LED chip to align with a pad-group on the display backplane.

A first aspect of the disclosure provides a method for mass transfer. The method includes the following. An insulating-adhesive is applied on a growth substrate, where the insulating-adhesive applied is between any two adjacent light-emitting diode (LED) chips on the growth substrate. The growth substrate is placed above a display backplane, where a distance between the growth substrate and the display backplane after placing is greater than a height of an LED chip. An insulating-adhesive column is formed between the growth substrate and the display backplane by softening the insulating-adhesive through heating, where the softened insulating-adhesive subjected to heating is adhered to the display backplane. An LED chip is separated from the growth substrate, to make the separated LED chip fall onto a corresponding pad-group through a channel formed by insulating-adhesive columns around the separated LED chip. The fallen LED chip is bonded with the corresponding pad-group on the display backplane.

According to the method for mass transfer, LED chips can be transferred to the display backplane from the growth substrate directly, which greatly simplifies a transfer process. Moreover, in the transfer process, only one type of adhesive (i.e., insulating-adhesive) is required, that is, less consumable is required, and thus, the cost of the entire transfer process can be reduced. In addition, an adhesive force of the insulating-adhesive can play the role of supporting the growth substrate and the display backplane, which can ensure precise alignment of the LED chip and the pad-group. As such, a welding strength of the LED chip can be guaranteed, thereby ensuring normal connection between the LED chip and the drive circuit and preventing falling of the LED chip from the display backplane.

In some implementations, the insulating-adhesive is spaced apart from any two adjacent LED chips. The insulating-adhesive is spaced apart from any two adjacent LED chips, and accordingly, the insulating-adhesive column formed by the insulating-adhesive is also spaced apart from the two adjacent LED chips, which can prevent the insulating-adhesive column from being adhered to the LED chip when the LED chip is stripped off, and can avoid affecting luminous brightness and luminous consistency of the LED chip.

In some implementations, the insulating-adhesive is applied on the growth substrate, where the insulating-adhesive between any two adjacent LED chips has a cross section with narrow ends and wide middle. The cross section refers to a cross section of the insulating-adhesive in a thickness direction of the insulating-adhesive. The insulating-adhesive is in a shape with narrow ends and wide middle, which can ensure that the insulating-adhesive does not contact the LED chip, has sufficient adhesive force, and has sufficient volume.

In some implementations, the insulating-adhesive is applied on the growth substrate, where the insulating-adhesive between any two adjacent LED chips has a cross section in a shape of a circle, an ellipse, or two isosceles trapezoids butted at two longer sides among two pairs of parallel sides. The cross section refers to a cross section of the insulating-adhesive in a thickness direction of the insulating-adhesive. The insulating-adhesive is in a shape with narrow ends and wide middle, which can ensure that the insulating-adhesive does not contact the LED chip, has sufficient adhesive force, and has sufficient volume.

In some implementations, the insulating-adhesive column is formed between the growth substrate and the display backplane, where the insulating-adhesive column has a cross section with narrow ends and wide middle. In some implementations, the insulating-adhesive column formed between the growth substrate and the display backplane has a cross section in a shape of an ellipse. The cross section refers to a cross section in a thickness direction of the insulating-adhesive column.

As such, a narrow end of the insulating-adhesive column is adhered to the growth substrate, which can ensure that the insulating-adhesive column does not contact the LED chip while realizing adhesion of the insulating-adhesive column and the growth substrate. The insulating-adhesive column is wide in the middle, so that the insulating-adhesive column is sufficient in volume, which allows the insulating-adhesive column to provide enough support for the growth substrate and the display backplane, to avoid changes in a relative position of the growth substrate to the display backplane. The other narrow end of the insulating-adhesive column is adhered to the display backplane, which can ensure that the insulating-adhesive column does not contact the pad-group while realizing adhesion of the insulating-adhesive column and display backplane.

In some implementations, the insulating-adhesive column is formed between the growth substrate and the display backplane, where the insulating-adhesive column has a cross section in a shape of an ellipse. As such, it is ensured that the insulating-adhesive column does not contact the LED chip and the pad-group, has sufficient adhesive force, and has sufficient volume to provide support for the growth substrate and display backplane.

In some implementations, the insulating-adhesive column is formed between the growth substrate and the display backplane, and is spaced apart from any two adjacent LED chips. As such, the insulating-adhesive column can be prevented from being adhered to the LED chip when the LED chip is stripped off, so as to avoid affecting luminous brightness and luminous consistency of the LED chip.

In some implementations, the insulating-adhesive is applied on the growth substrate, where the insulating-adhesive is between any two adjacent LED chips and is lower than or flush with the LED chip. As such, the insulating-adhesive can be prevented from being too thick, which can avoid weakening of a welding strength caused by flowing of the insulating-adhesive into a space between the LED chip and a pad-group when welding the LED chip and the pad-group. In addition, raw materials can also be saved, thereby reducing costs.

In some implementations, before applying the insulating-adhesive on the growth substrate, the method further includes the following. A first groove is defined between any two adjacent LED chips on the growth substrate. Applying the insulating-adhesive, which is between any two adjacent LED chips, on the growth substrate is as follows. The insulating-adhesive is applied on the growth substrate, where the insulating-adhesive is between any two adjacent LED chips, and at least part of the insulating-adhesive applied is in the first groove. As such, the first groove can guide flowing of the insulating-adhesive after the insulating-adhesive is softened, which can prevent the insulating-adhesive from flowing to contact with the LED chip.

In some implementations, before softening the insulating-adhesive, the method further includes the following. A second groove is defined between adjacent pad-groups on the display backplane. Forming the insulating-adhesive column between the growth substrate and the display backplane is as follows. The insulating-adhesive column is formed between the growth substrate and the display backplane with at least part of the insulating-adhesive adhered to the display backplane extended into the second groove. As such, the second groove can guide flowing of the insulating-adhesive after the insulating-adhesive is softened, which can prevent the insulating-adhesive from flowing to contact with the pad-group.

In some implementations, the distance between the growth substrate and the display backplane is in a range of 20 microns to 70 microns. As such, the softened insulating-adhesive can flow to be well adhered to the display backplane, which can ensure that the softened insulating-adhesive has sufficient adhesive force to the LED chip, so that the LED chip can be supported in a position where the LED chip 20 can achieve precise alignment with the pad-group; on the other hand, the softened insulating-adhesive does not flow onto the display backplane too much, which can ensure that the pad-group is not affected by the insulating-adhesive.

In some implementations, before applying the insulating-adhesive on the growth substrate, the method further includes the following. Detect a defective LED chip on the growth substrate. Separating the LED chip from the growth substrate is as follows. At least part of LED chips other than the defective LED chip is separated from the growth substrate. As such, it is ensured that LED chips transferred to the display backplane are LED chips with normal appearance and good wavelength consistency, so that a prepared display device has better luminous consistency, thereby improving quality of the prepared display device.

In some implementations, after separating from the growth substrate the at least part of LED chips other than the defective LED chip, the method further includes the following. A further LED chip is supplemented to a pad-group corresponding to the defective LED chip. As such, vacancy at the pad-group corresponding to the defective LED chip can be avoided, which can realize that pixels on the prepared display device are relatively complete, thereby improving a display effect.

In some implementations, an adhesive force of the insulating-adhesive column to the display backplane is smaller than an adhesive force of the insulating-adhesive column to the growth substrate. As such, the insulating-adhesive column can be taken away together with the growth substrate when removing the growth substrate, thereby realizing separating of the insulating-adhesive column from the display backplane. As such, it can avoid affecting display of the LED chip due to residue of the insulating-adhesive column on the display backplane, and avoid poor heat dissipation of a prepared LED display device due to residue of the insulating-adhesive column.

In some implementations, a temperature for heating is in a range of 120° C. to 140° C. This temperature is lower than a melting point of solder for preparing the pad-group, which can prevent the solder from melting. In addition, within the above temperature range, fluidity of the insulating-adhesive column is good, which can ensure that part of the insulating-adhesive can flow to be adhered to the display backplane, another part of the insulating-adhesive can remain attached to the growth substrate, and other part of the insulating-adhesive is between the display backplane and the growth substrate, to make the display backplane and the growth substrate be connected temporarily, so that a position of the display backplane to the growth substrate can be kept relatively fixed.

A second aspect of the disclosure provides an LED display device. The LED display device includes a display backplane and multiple LED chips. The multiple LED chips are transferred to the display backplane by the above method for mass transfer described in the first aspect of the disclosure.

A third aspect of the disclosure provides a display apparatus. The display apparatus includes a drive circuit and the LED display device described in the second aspect of the disclosure. The LED display device is electrically connected to the drive circuit.

According to the method for mass transfer, LED chips can be transferred to the display backplane from the growth substrate directly, which greatly simplifies a transfer process. Moreover, in the transfer process, only one type of adhesive (i.e., insulating-adhesive) is required, that is, less consumable is required, and thus, the cost of the entire transfer process can be reduced. In addition, an adhesive force of the insulating-adhesive can play the role of supporting the growth substrate and the display backplane, which can ensure precise alignment of the LED chip and the pad-group. As such, a welding strength of the LED chip can be guaranteed, thereby ensuring normal connection between the LED chip and the drive circuit and preventing falling of the LED chip from the display backplane.

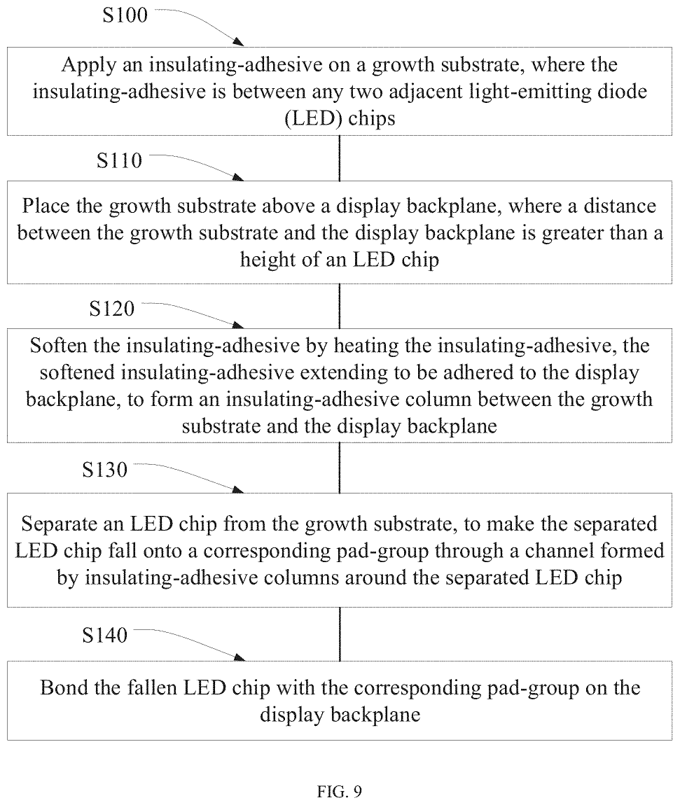

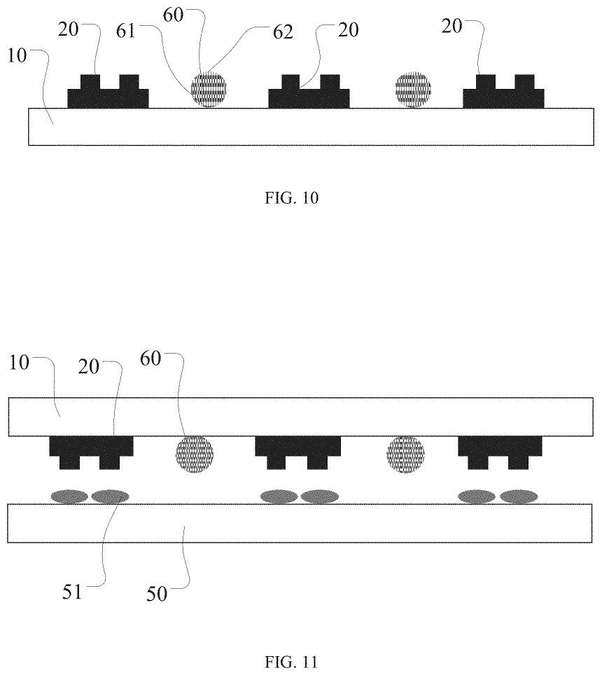

In order to solve the above problems, implementations of the disclosure provide a method for mass transfer. Referring to FIG. 9 to FIG. 13, FIG. 9 is a schematic flowchart illustrating a method for mass transfer provided in implementations of the disclosure. FIG. 10 to FIG. 13 are schematic diagrams illustrating processes of a method for mass transfer provided in implementations of the disclosure. The method for mass transfer includes the following.

Referring to FIG. 10, at S100, an insulating-adhesive 60 is applied on a growth substrate 10, where the insulating-adhesive 60 is between any two adjacent LED chips 20. The insulating-adhesive 60 is a non-conductive adhesive film (NCF). The stickiness of the NCF is sensitive to temperature changes.

It should be understood that, LED chips 20 are generally arranged in an array on the growth substrate 10, there is a gap between any two adjacent LED chips 20, and multiple gaps cooperatively form a channel. Also, those skilled in the art should understand that, in order to make the insulating-adhesive 60 and the bonded LED chip 20 be spaced apart from one another, the insulating-adhesive 60 cannot fill the entire channel. As such, the LED chip 20 can be prevented from being in contact with the insulating-adhesive 60, and an insulating-adhesive column 70 formed by the insulating-adhesive 60 can be prevented from being adhered to the LED chip 20 when the LED chip 20 is stripped off from the growth substrate 10, thereby preventing the adhesive from affecting luminous brightness and luminous consistency of the LED chip 20.

In some implementations, the insulating-adhesive 60 is applied on the growth substrate 10 as follows. The insulating-adhesive 60 is applied on the growth substrate 10, where in a thickness direction of the insulating-adhesive 60, the insulating-adhesive 60 has a cross section with narrow ends and wide middle.

In some implementations, the insulating-adhesive 60 has a first cross section in the thickness direction of the insulating-adhesive 60, and the first cross section has a first bottom edge 61 in contact with the growth substrate 10 and a second bottom edge 62 away from the growth substrate 10. A width of the insulating-adhesive 60 increases gradually from the first bottom edge 61 to the middle of the insulating-adhesive 60, and the width of the insulating-adhesive 60 increases gradually from the second bottom edge 62 to the middle of the insulating-adhesive 60.

That is, a width of the first cross section of the insulating-adhesive 60 increases gradually from two ends to the middle in the thickness direction of the insulating-adhesive 60. Since the insulating-adhesive 60 is easily in contact with the LED chip 20 at positions of the first bottom edge 61 and the second bottom edge 62, the first bottom edge 61 and the second bottom edge 62 are set relatively narrow. As such, the insulating-adhesive 60 not only can be adhered to the growth substrate 10, but also can be ensured not to be in contact with the LED chip 20. The width of the first cross section at positions between the first bottom edge 61 and the second bottom edge 62 increases gradually, so that the insulating-adhesive 60 is sufficient in volume, which allows the softened insulating-adhesive 60 to flow to be adhered to the display backplane 50.

In some implementations, applying the insulating-adhesive 60, which is between any two adjacent LED chips 20, on the growth substrate 10 is as follows. The insulating-adhesive 60 is applied on the growth substrate 10, where the insulating-adhesive 60 between any two adjacent LED chips 20 has a cross section in a shape of a circle or an ellipse.

That is, the first cross section may be in a shape of a circle. It should be understood that, since the insulating-adhesive 60 is sticky, the insulating-adhesive 60 is deformed at contact positions with the growth substrate 10, that is, the first (circular) cross section at contact positions with the growth substrate 10 is in a straight line, and thus, the first cross section is not a standard circle. The first cross section is in a shape of a circle, which can realize that the first cross section is narrow at two ends and wide in the middle, thereby ensuring that the insulating-adhesive 60 does not contact the LED chip 20, has sufficient adhesive force, and has sufficient volume.

In other implementations, the first cross section is in a shape of an ellipse, and a long axis of an ellipse to which the first cross section belongs is parallel to the thickness direction of the insulating-adhesive 60. Positions where the first cross section contacts the growth substrate 10 are also in a straight line. The first cross section is in a shape of an ellipse, which can realize that the first cross section is narrow at two ends and wide in the middle, thereby ensuring that the insulating-adhesive 60 does not contact the LED chip 20, has sufficient adhesive force, and has sufficient volume to adhere to the display backplane 50 subsequently.

In other implementations, the first cross section is in a shape combined by two isosceles trapezoids butted through two longer sides (i.e., lower bases) among two pairs of parallel sides, where a shorter side (i.e., upper base) among parallel sides of one isosceles trapezoid is in contact with the growth substrate 10. The first cross section is in such a shape, which can realize that the first cross section is narrow at two ends and wide in the middle, thereby ensuring that the insulating-adhesive 60 does not contact the LED chip 20, has sufficient adhesive force, and has sufficient volume to adhere to the display backplane 50 subsequently.

In some implementations, applying the insulating-adhesive 60, which is between any two adjacent LED chips 20, on the growth substrate 10 is as follows. The insulating-adhesive 60 is applied on the growth substrate 10, where the insulating-adhesive 60 is between any two adjacent LED chips 20, and is lower than or flush with the LED chip 20. In some implementations, the insulating-adhesive 60 has a first surface away from the growth substrate 10 and a second surface connected with the growth substrate 10. The first surface can be processed to be flush with a side surface of the LED chip 20 away from the growth substrate 10, or can be processed to be lower than the side surface of the LED chip 20 away from the growth substrate 10. As such, the insulating-adhesive 60 can be prevented from being too thick, which can avoid weakening of a welding strength caused by flowing of the insulating-adhesive 60 into a space between the LED chip 20 and a pad-group 51 when welding the LED chip 20 and the pad-group 51. In addition, raw materials can also be saved, thereby reducing costs.

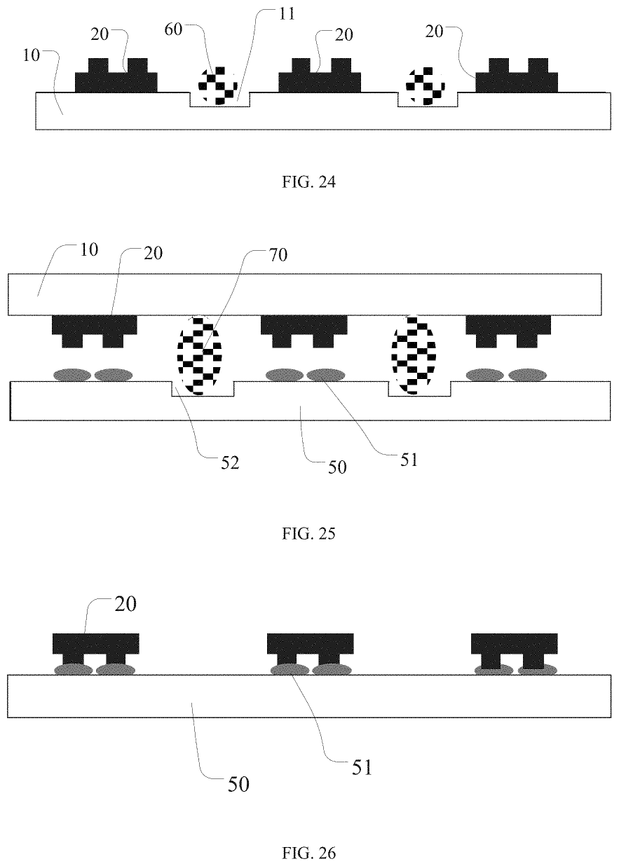

In some implementations, before applying the insulating-adhesive 60 on the growth substrate 10, the method further includes the following. A first groove 11 is defined between any two adjacent LED chips 20 on the growth substrate 10. Applying the insulating-adhesive 60, which is between any two adjacent LED chips 20, on the growth substrate 10 is as follows. The insulating-adhesive 60 is applied on the growth substrate 10, where the insulating-adhesive 60 is between any two adjacent LED chips 20, and at least part of the insulating-adhesive 60 is in the first groove 11. Referring to FIG. 24, the first groove 11 may be defined in the channel. When filling the insulating-adhesive 60 into the channel, at least part of the insulating-adhesive 60 is in the first groove 11. As such, the first groove 11 can guide flowing of the insulating-adhesive 60 after the insulating-adhesive 60 is softened, which can prevent the insulating-adhesive 60 from flowing to contact with the LED chip 20.

At S110, referring to FIG. 11, the growth substrate 10 is placed above a display backplane 50, where a distance between the growth substrate 10 and the display backplane 50 is greater than a height of an LED chip 20. The display backplane 50 may be a thin-film transistor (TFT) substrate, a printed circuit board (PCB), etc., which is not limited in the disclosure. That is, the growth substrate 10 is placed above and spaced apart from the display backplane 50. Since the LED chip 20 need to be welded to a pad-group 51 on the display backplane 50 eventually, multiple LED chips 20 need to be in one-to-one correspondence with multiple pad-groups 51 on the display backplane 50.

It can be understood that, the distance between the growth substrate 10 and the display backplane 50 refers to a distance between a surface of the growth substrate 10 facing the display backplane 50 and a surface of the display backplane 50 facing the growth substrate 10.

Generally, the display backplane 50 is provided with a drive circuit and the like, and the drive circuit can drive the LED chip 20 to realize light emission of the LED chip 20, thereby ensuring that a related display can work normally. The pad-group 51 on the display backplane 50 may be formed by applying solder such as solder paste on the display backplane 50 in dots.

In some implementations, the growth substrate 10 is placed above the display backplane 50, where the distance between the growth substrate 10 and the display backplane 50 is greater than or equal to 20 microns. If the growth substrate 10 is too close to the display backplane 50, it may cause the softened insulating-adhesive 60 to flow onto the display backplane 50 too much, so that covering of the pad-group 51 occurs. As a result, it may cause poor welding between the pad-group 51 and the LED chip 20. Conversely, if the growth substrate 10 is too far from the display backplane 50, it may cause the insulating-adhesive 60 to extend too long between the display backplane 50 and the growth substrate 10 when the insulating-adhesive 60 flows onto the display backplane 50, which will affect an adhesive force of the insulating-adhesive 60 to the display backplane 50. As a result, the insulating-adhesive 60 may be tilted, thereby affecting precision of alignment of the LED chip 20.

By setting such a distance, on the one hand, the softened insulating-adhesive 60 can flow to be well adhered to the display backplane 50, which can ensure that the insulating-adhesive 60 has sufficient adhesive force to the display backplane 50, so that the LED chip 20 can be supported in a position where the LED chip 20 can achieve precise alignment with the pad-group 51; on the other hand, the softened insulating-adhesive 60 does not flow onto the display backplane 50 too much, which can ensure that the pad-group 51 is not affected by the insulating-adhesive 60.

In some implementations, the growth substrate 10 is placed above the display backplane 50, where the distance between the growth substrate 10 and the display backplane 50 is further less than or equal to 70 microns. As such, an adhesive force of the insulating-adhesive 60 to the display backplane 50 can be prevented from being too weak due to the display backplane 50 being too far away from the growth substrate 10.

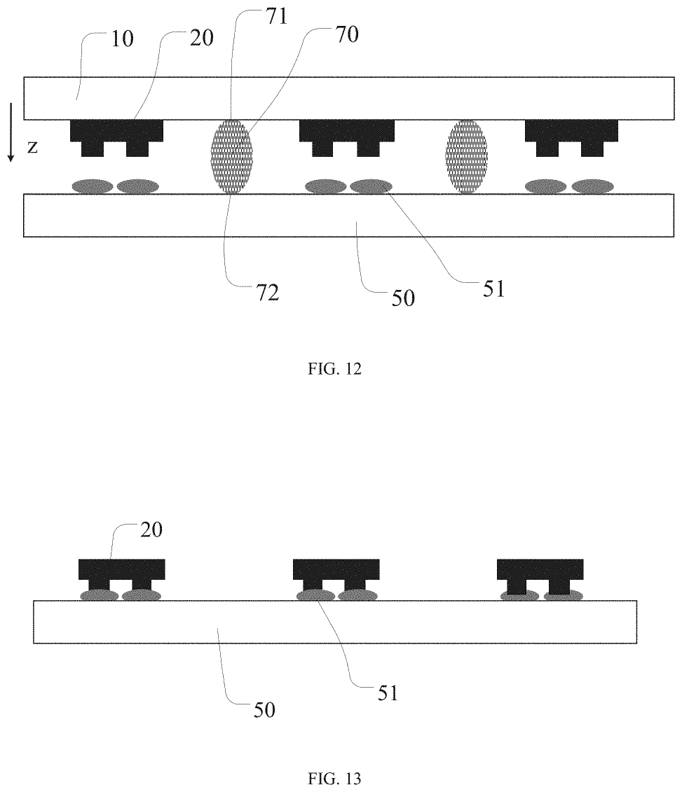

At S120, referring to FIG. 12, the insulating-adhesive 60 is softened by heating the insulating-adhesive 60, where the softened insulating-adhesive 60 extends to be adhered to the display backplane 50, to form an insulating-adhesive column 70 between the growth substrate 10 and the display backplane 50. In some implementations, the insulating-adhesive 60 is softened by laser heating.

In some implementations, the insulating-adhesive column 70 is formed between the growth substrate 10 and the display backplane 50, where the insulating-adhesive column 70 is spaced apart from two adjacent LED chips 20. As such, the insulating-adhesive column 70 can be prevented from being adhered to the LED chip 20 when the LED chip 20 is stripped off, thereby preventing the adhesive from affecting luminous brightness and luminous consistency of the LED chip.

Referring to FIG. 23, curve L1 is a temperature curve, and curve L2 is a stickiness curve of the insulating-adhesive 60. As can be seen, when temperature T rises from 20 degrees Celsius (° C.) to about 120° C., the stickiness of the insulating-adhesive 60 continues to decrease. When temperature T rises from 120° C. to 180° C., the stickiness remains basically unchanged. When temperature T rises from 180° C. and 200° C., the stickiness starts to increase.

Based on the above, a temperature for heating can be controlled to be in a range of 120° C. to 140° C., and this temperature is lower than a melting point of solder for preparing the pad-group 51, which can prevent the solder from melting. In addition, within the above temperature range, fluidity of the insulating-adhesive column 70 is good, which can ensure that part of the insulating-adhesive 60 can flow to be adhered to the display backplane 50, another part of the insulating-adhesive 60 can remain attached to the growth substrate 10, and other part of the insulating-adhesive 60 is between the display backplane 50 and the growth substrate 10, to make the display backplane 50 and the growth substrate 10 be connected temporarily, so that a position of the display backplane 50 to the growth substrate 10 can be kept relatively fixed.

When heating is stopped, the temperature begins to drop, and the stickiness of the insulating-adhesive 60 will increase as the temperature drops. In this situation, the insulating-adhesive 60 will cool down, so that the growth substrate 10 can be well adhered to the display backplane 50, and the growth substrate 10 and the display backplane 50 can be supported by the insulating-adhesive column 70. As such, a position of the growth substrate 10 to the display backplane 50 is relatively fixed, so that the LED chip 20 can precisely correspond to the pad-group 51 in positions, thereby improving precision of alignment of the LED chip 20.

In some implementations, before softening the insulating-adhesive 60, the method further includes: defining a second groove 52 between adjacent pad-groups 51 on the display backplane 50. The insulating-adhesive 60 is softened, where the softened insulating-adhesive 60 extends to be adhered to the display backplane 50, and the insulating-adhesive column 70 is formed between the growth substrate 10 and the display backplane 50 with extending into the second groove 52 at least part of the insulating-adhesive 60 adhered to the display backplane 50. Referring to FIG. 25, the second groove 52 is defined between adjacent pad-groups 51 on the display backplane 50, so that at least part of the softened insulating-adhesive 60 can flow into the second groove 52 when part of the softened insulating-adhesive 60 flows to be adhered to the display backplane 50. As such, the second groove 52 can guide flowing of the insulating-adhesive 60 after the insulating-adhesive 60 is softened, which can prevent the insulating-adhesive 60 from flowing to contact with the pad-group 51.

In some implementations, the insulating-adhesive column 70 is formed between the growth substrate 10 and the display backplane 50 as follows. The insulating-adhesive column is formed between the growth substrate 10 and the display backplane 50, where the insulating-adhesive column 70 has a cross section with narrow ends and wide middle. As such, a narrow end of the insulating-adhesive column 70 is adhered to the growth substrate 10, which can ensure that the insulating-adhesive column 70 does not contact the LED chip 20, while realizing adhesion of the insulating-adhesive column 70 and the growth substrate 10. The insulating-adhesive column 70 is wide in the middle, so that the insulating-adhesive column 70 is sufficient in volume, which allows the insulating-adhesive column 70 to provide enough support for the growth substrate 10 and the display backplane 50, to avoid changes in a relative position of the growth substrate 10 to the display backplane 50. The other narrow end of the insulating-adhesive column 70 is adhered to the display backplane 50, which can ensure that the insulating-adhesive column 70 does not contact the pad-group 51, while realizing adhesion of the insulating-adhesive column 70 and the display backplane 50.

In some implementations, the insulating-adhesive column 70 has a second cross section in a thickness direction (z) of the insulating-adhesive column 70, where the second cross section has a third bottom edge 71 in contact with the growth substrate 10 and a fourth bottom edge 72 in contact with the display backplane 50. A width of the insulating-adhesive column 70 increases gradually from the third bottom edge 71 to the middle of the insulating-adhesive column 70, and the width increases gradually from the fourth bottom edge 72 to the middle of the insulating-adhesive column 70.

That is, a width of the second cross section of the insulating-adhesive column 70 increases gradually from two ends to the middle in the thickness direction of the insulating-adhesive column 70. Since the insulating-adhesive column 70 is easily in contact with the LED chip 20 at positions of the third bottom edge 71, the third bottom edge 71 is set relatively narrow. As such, the insulating-adhesive column 70 not only can be adhered to the growth substrate 10, but also can be ensured not to be in contact with the LED chip 20. Also, since the insulating-adhesive column 70 is easily in contact with the pad-group 51 at positions of the fourth bottom edge 72, the fourth bottom edge 72 is set relatively narrow. As such, the insulating-adhesive column 70 not only can be adhered to the display backplane 50, but also can be ensured not to be in contact the pad-group 51. The width of the insulating-adhesive column 70 at positions between the third bottom edge 71 and the fourth bottom edge 72 increases gradually, so that the insulating-adhesive column 70 is sufficient in volume, which allows the insulating-adhesive column 70 to provide enough support for the growth substrate 10 and the display backplane 50, to avoid changes in a relative position of the growth substrate 10 to the display backplane 50.

In some implementations, the second cross section is in a shape of an ellipse, and a long axis of an ellipse to which the second cross section belongs is parallel to the thickness direction of the insulating-adhesive column 70. Positions where the second cross section contacts the growth substrate 10 are also in a straight line. The second cross section is in a shape of an ellipse, which can realize that the second cross section is narrow at two ends and wide in the middle, thereby ensuring that the insulating-adhesive column 70 does not contact the LED chip 20 and the pad-group 51, has sufficient adhesive force, and has sufficient volume to provide support for the growth substrate 10 and the display backplane 50.

In other implementations, the second cross section is in a shape combined by two isosceles trapezoids butted through two longer sides (i.e., lower bases) among two pairs of parallel sides, where a shorter side (i.e., upper base) among parallel sides of one isosceles trapezoid is in contact with the growth substrate 10. The second cross section is in such a shape, which can realize that the second cross section is narrow at two ends and wide in the middle, thereby ensuring that the insulating-adhesive column 70 does not contact the LED chip 20 and the pad-group 51, has sufficient adhesive force, and has sufficient volume to provide support for the growth substrate 10 and the display backplane 50.

At S130, referring to FIG. 13, the LED chip 20 is separated from the growth substrate 10 by laser lift-off, to make the separated LED chip 20 fall onto a corresponding pad-group 51 through a channel formed by insulating-adhesive columns 70 around the separated LED chip 20. Since a position of the growth substrate 10 to the display backplane 50 is relatively fixed when the insulating-adhesive column 70 is connected to the growth substrate 10 and the display backplane 50, precision of alignment of the LED chip 20 and the pad-group 51 can be guaranteed, and thus, the LED chip 20, when falling, can precisely fall onto a corresponding pad-group 51. As such, accuracy of a position of the LED chip 20 can be improved, thereby achieving well welding of the LED chip 20.

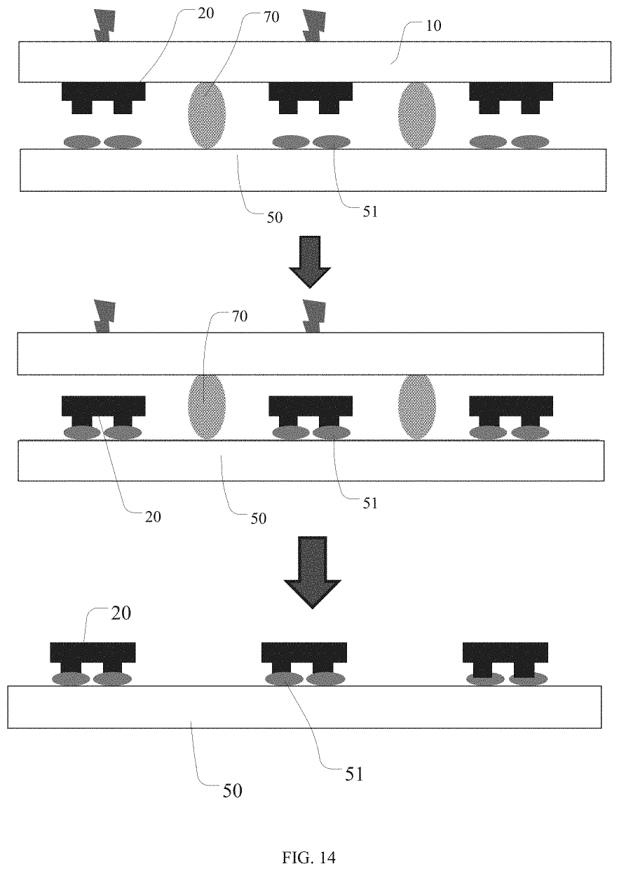

The separating of the LED chip 20 from the growth substrate 10 and the separating of the insulating-adhesive column 70 from the display backplane 50 are as follows. Referring to FIG. 14, FIG. 14 is a schematic diagram illustrating a specific flow of a process illustrated in FIG. 13. In some implementations, LED chips 20 are selectively stripped off from the growth substrate 10 by using a laser. A mask may be used to block a position that does not require laser irradiation, to prevent the insulating-adhesive column 70 from being irradiated by the laser. After the LED chip 20 is separated from the growth substrate 10, the growth substrate 10 is removed. In some implementations, the growth substrate 10 is moved to other positions by using a tool.

Since the display backplane 50 is made of metal and the insulating-adhesive column 70 has poor wettability (also called “degree of wetting”) with metal, an adhesive force of the insulating-adhesive column 70 to the display backplane 50 is smaller than an adhesive force of the insulating-adhesive column 70 to the growth substrate 10, and thus, the insulating-adhesive column 70 can be taken away together with the growth substrate 10 when removing the growth substrate 10 with a tool, thereby realizing the separating of the insulating-adhesive column 70 from the display backplane 50. As such, it can avoid affecting display of the LED chip 20 due to residue of the insulating-adhesive column 70 on the display backplane 50, and avoid poor heat dissipation of a prepared LED display device due to residue of the insulating-adhesive column 70.

At S140, the fallen LED chip 20 is bonded to the corresponding pad-group 51 on the display backplane 50. In some implementations, the bonding is performed by heating and pressing. At S130, the LED chip 20 precisely falls to contact with the pad-group 51, and accordingly, the LED chip 20, when bonded, can correspond to the pad-group 51 precisely, thereby improving alignment precision.

It should be understood that, the above processes are depicted by taking only one type of LED chips (e.g., red LED chips) as an example, and a transfer method for other color types of LED chips (e.g., green LED chips, and blue LED chips) is the same as a transfer method for the red LED chips, which will not be repeated in implementations of the disclosure.

As can be seen, according to the method for mass transfer of these implementations, LED chips 20 can be transferred to the display backplane 50 from the growth substrate 10 directly, which greatly simplifies a transfer process. Moreover, in the transfer process, only one type of adhesive (i.e., insulating-adhesive 60) is required, that is, less consumable is required, and thus, the cost of the entire transfer process can be reduced. In addition, an adhesive force of the insulating-adhesive 60 can play the role of supporting the growth substrate 10 and the display backplane 50, which can ensure precise alignment of the LED chip 20 and the pad-group 51. As such, a welding strength of the LED chip 20 can be guaranteed, thereby ensuring normal connection between the LED chip 20 and the drive circuit and preventing falling of the LED chip 20 from the display backplane 50.

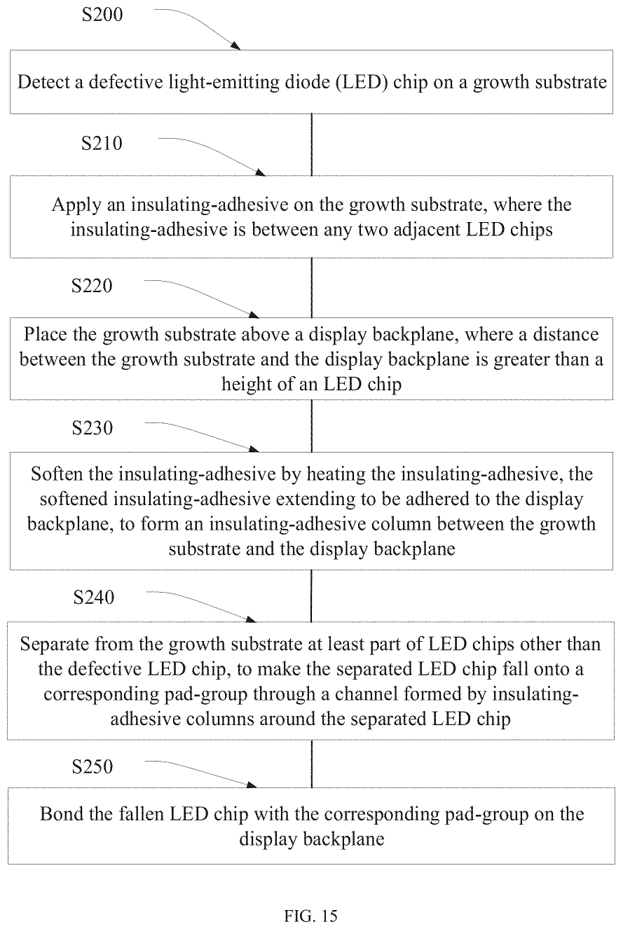

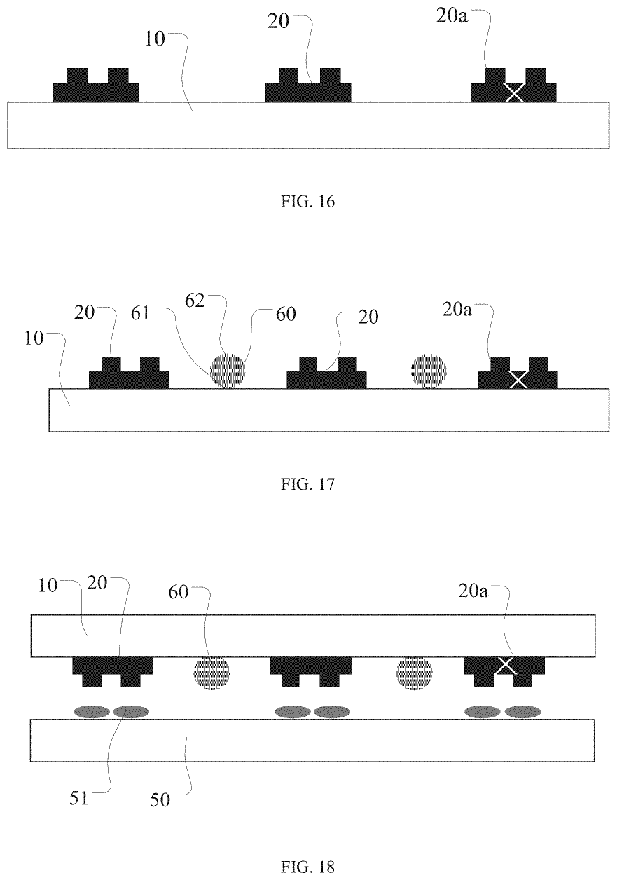

Other implementations of the disclosure provide a method for mass transfer. Referring to FIG. 15 to FIG. 20, FIG. 15 is a schematic flowchart illustrating a method for mass transfer provided in other implementations of the disclosure, and FIG. 16 to FIG. 20 are schematic diagrams illustrating processes of a method for mass transfer provided in other implementations of the disclosure. The method for mass transfer of these implementations includes the following.

At S200, referring to FIG. 16, detect a defective LED chip 20a on a growth substrate 10. In some implementations, micro automated optical inspection (AOI) or micro photoluminescence (PL) detection equipment is used to detect optical characteristics and appearance quality of an LED chip 20 on the growth substrate 10, to generate corresponding mapping data. In this way, the defective LED chip 20a on the growth substrate 10 can be known. Therefore, when transferring LED chips to the display backplane 50, transferring of the defective LED chip 20a can be avoided, which can ensure that LED chips 20 transferred to the display backplane 50 have good appearance and good wavelength consistency.

At S210, referring to FIG. 17, an insulating-adhesive 60 is applied on the growth substrate 10, where the insulating-adhesive 60 is between any two adjacent LED chips 20. This operation is the same as the operation at S100 of the foregoing implementations, which will not be repeated herein.

At S220, referring to FIG. 18, the growth substrate 10 is placed above a display backplane 50, where a distance between the growth substrate 10 and the display backplane 50 is greater than a height of an LED chip 20. This operation is the same as the operation at S110 of the foregoing implementations, which will not be repeated herein.

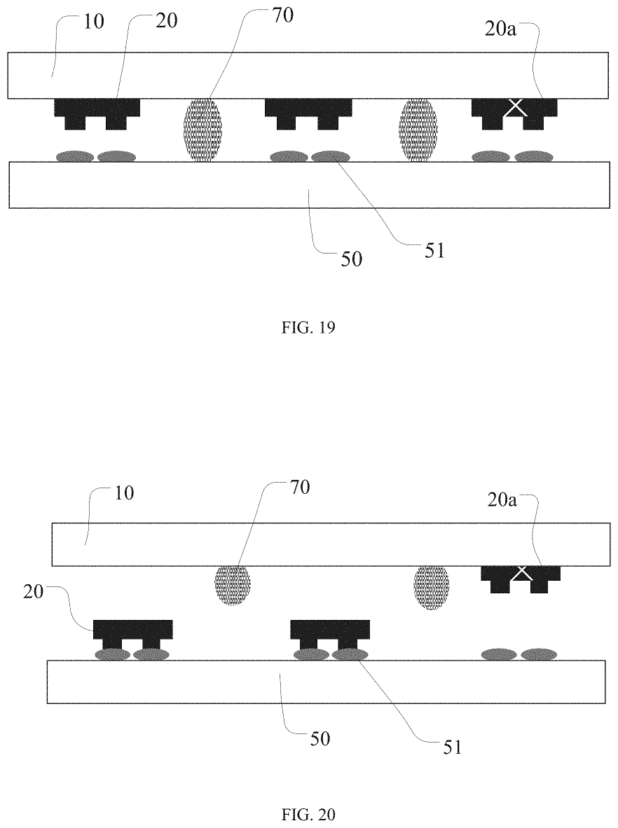

At S230, referring to FIG. 19, the insulating-adhesive 60 is softened by heating the insulating-adhesive 60, where the softened insulating-adhesive 60 extends to be adhered to the display backplane 50, to form an insulating-adhesive column 70 between the growth substrate 10 and the display backplane 50. This operation is the same as the operation at S120 of the foregoing implementations, which will not be repeated herein.

At S240, referring to FIG. 20, by laser lift-off, at least part of LED chips 20 other than the defective LED chip 20a is separated from the growth substrate 10, to make the separated LED chip 20 fall onto a corresponding pad-group 51 through a channel formed by insulating-adhesive columns 70 around the separated LED chip 20. In this way, the LED chip 20 can fall to contact with the pad-group 51. Since a position of the growth substrate 10 to the display backplane 50 is relatively fixed when the insulating-adhesive column 70 is connected to the growth substrate 10 and the display backplane 50, precision of alignment of the LED chip 20 and the pad-group 51 can be guaranteed, and thus, the LED chip 20, when falling, can precisely fall onto a corresponding pad-group 51.

The defective LED chip(s) 20a can be detected at S200. Accordingly, when massively transferring LED chips 20 to the display backplane 50, the defective LED chip(s) 20a will not be transferred, and LED chips 20 with normal appearance and good wavelength consistency can be selected for transfer.

In some implementations, the laser selectively irradiates a normal LED chip(s) 20, while avoiding the defective LED chip(s) 20a, so that the normal LED chip(s) 20 is stripped off from the growth substrate 10 while the defective LED chip(s) 20a remains on the growth substrate 10. When removing the growth substrate 10, the defective LED chip(s) 20a can be removed together with the growth substrate 10. As such, it is ensured that LED chips 20 transferred to the display backplane 50 are LED chips 20 with normal appearance and good wavelength consistency, so that a prepared display device has better luminous consistency, thereby improving quality of the prepared display device.

At S250, by heating and pressing, the fallen LED chip 20 is bonded with the corresponding pad-group 51 on the display backplane 50.

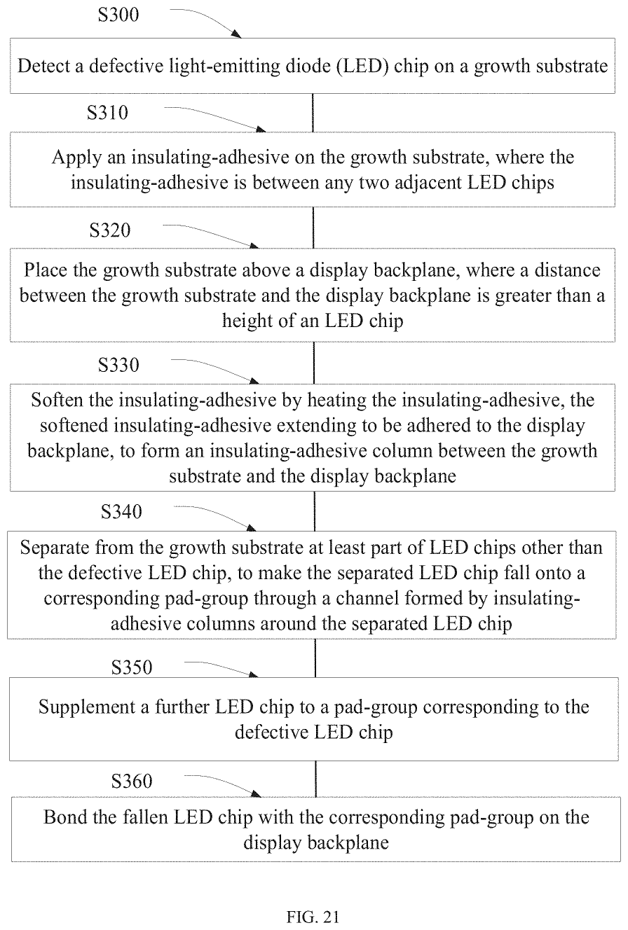

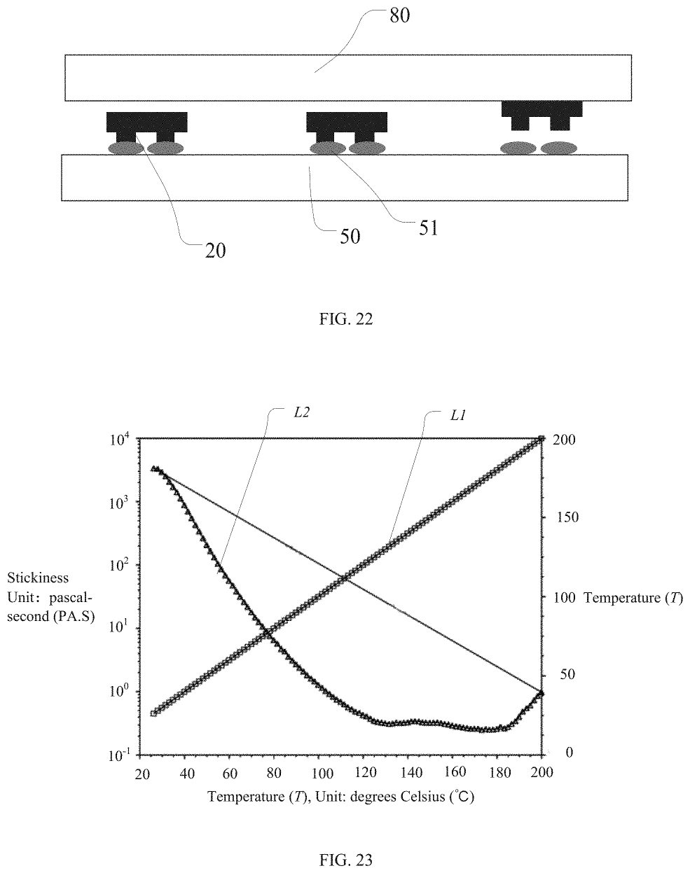

Other implementations of the disclosure provide a method for mass transfer. Referring to FIG. 21 and FIG. 22, FIG. 21 is a schematic flowchart illustrating a method for mass transfer provided in other implementations of the disclosure, and FIG. 22 is a schematic diagram illustrating a process of the operation S350 in FIG. 21.

The method for mass transfer of these implementations includes the following.

At S300, detect a defective LED chip 20a on a growth substrate 10. This operation is the same as the operation at S200 of the foregoing implementations, which will not be repeated herein.

At S310, an insulating-adhesive 60 is applied on the growth substrate 10, where the insulating-adhesive 60 is between any two adjacent LED chips 20. This operation is the same as the operation at S100 of the foregoing implementations, which will not be repeated herein.

At S320, the growth substrate 10 is placed above a display backplane 50, where a distance between the growth substrate 10 and the display backplane 50 is greater than a height of an LED chip 20. This operation is the same as the operation at S110 of the foregoing implementations, which will not be repeated herein.

At S330, the insulating-adhesive 60 is softened by heating the insulating-adhesive 60, where the softened insulating-adhesive 60 extends to be adhered to the display backplane 50, to form an insulating-adhesive column 70 between the growth substrate 10 and the display backplane 50. This operation is the same as the operation at S120 of the foregoing implementations, which will not be repeated herein.

At S340, by laser lift-off, at least part of LED chips 20 other than the defective LED chip 20a is separated from the growth substrate 10, to make the separated LED chip 20 fall onto a corresponding pad-group 51 through a channel formed by insulating-adhesive columns 70 around the separated LED chip. This operation is the same as the operation at S240 of the foregoing implementations, which will not be repeated herein.

At S350, referring to FIG. 22, a further LED chip 20 is supplemented to a pad-group 51 corresponding to the defective LED chip 20a. As such, vacancy at the pad-group 51 corresponding to the defective LED chip 20a can be avoided, which can realize that pixels on the prepared display device are relatively complete, thereby improving a display effect.

At S360, by heating and pressing, the fallen LED chip 20 is bonded with the corresponding pad-group 51 on the display backplane 50.

In some implementations, a normal LED chip(s) 20 is adhered to a sticky repair board 80, and the normal LED chip 20 is transferred to the pad-group 51 corresponding to the defective LED chip 20a.

It should be understood by those skilled in the art that, no matter which of the foregoing implementations, the LED chip 20 needs to be welded to the pad-group 51 finally. In some implementations, the LED chip 20 is welded to the pad-group 51 by heating and pressing, to realize reliable connection of the LED chip 20, thereby improving quality of the display device.

According to the method for mass transfer of any of the foregoing implementations, referring to FIG. 26, other implementations of the disclosure provide a display device. The display device includes a display backplane 50 and multiple LED chips 20. The LED chips 20 are transferred to the display backplane 50 by using the method for mass transfer of any of the foregoing implementations.

Implementations of the disclosure further provide a display apparatus. The display apparatus includes a drive circuit and the LED display device described in any implementation of the disclosure. The LED display device is electrically connected to the drive circuit. The display apparatus may be a display apparatus with a display effect and/or a touch effect, such as a mobile phone, a tablet computer, a notebook computer, etc., which is not limited in the disclosure.

It should be understood that, the application of the disclosure is not limited to the foregoing exemplary implementations. Those of ordinary skill in the art may make improvements or equivalent substitutions to the disclosure according to the above descriptions, and all these improvements and equivalent substitutions, however, shall all be encompassed within the protection scope of the appended claims of the disclosure.

What is claimed is:

1. A method for mass transfer, comprising:
applying an insulating-adhesive on a growth substrate, wherein the insulating-adhesive applied is between any two adjacent light-emitting diode (LED) chips on the growth substrate;
placing the growth substrate above a display backplane, wherein a distance between the growth substrate and the display backplane after placing is greater than a height of an LED chip;
forming an insulating-adhesive column between the growth substrate and the display backplane by softening the insulating-adhesive through heating, wherein the softened insulating-adhesive subjected to heating is adhered to the display backplane;
separating an LED chip from the growth substrate, to make the separated LED chip fall onto a corresponding pad-group through a channel formed by insulating-adhesive columns around the separated LED chip; and
bonding the fallen LED chip with the corresponding pad-group on the display backplane.

2. The method for mass transfer of claim 1, wherein the insulating-adhesive is spaced apart from any two adjacent LED chips.

3. The method for mass transfer of claim 1, wherein in a thickness direction of the insulating-adhesive, the insulating-adhesive has a cross section with narrow ends and wide middle.

4. The method for mass transfer of claim 1, wherein the insulating-adhesive has a cross section in a shape of a circle, an ellipse, or two isosceles trapezoids butted at two longer sides among two pairs of parallel sides.

5. The method for mass transfer of claim 1, wherein the insulating-adhesive column has a cross section with narrow ends and wide middle.

6. The method for mass transfer of claim 1, wherein the insulating-adhesive column has a cross section in a shape of an ellipse.

7. The method for mass transfer of claim 1, wherein the insulating-adhesive column is spaced apart from any two adjacent LED chips.

8. The method for mass transfer of claim 1, wherein the insulating-adhesive is lower than or flush with the LED chip.

9. The method for mass transfer of claim 1, wherein before applying the insulating-adhesive on the growth substrate, the method further comprises:
defining a first groove between any two adjacent LED chips on the growth substrate, wherein at least part of the insulating-adhesive applied is in the first groove.

10. The method for mass transfer of claim 1, wherein
before softening the insulating-adhesive, the method further comprises:
defining a second groove between adjacent pad-groups on the display backplane; and
forming the insulating-adhesive column between the growth substrate and the display backplane comprises:
forming the insulating-adhesive column between the growth substrate and the display backplane with at least part of the insulating-adhesive adhered to the display backplane extended into the second groove.

11. The method for mass transfer of claim 1, wherein the distance between the growth substrate and the display backplane is in a range of 20 microns to 70 microns.

12. The method for mass transfer of claim 1, wherein
before applying the insulating-adhesive on the growth substrate, the method further comprises:
detecting a defective LED chip on the growth substrate; and
separating the LED chip from the growth substrate comprises:
separating from the growth substrate at least part of LED chips other than the defective LED chip.

13. The method for mass transfer of claim 12, wherein after separating from the growth substrate the at least part of LED chips other than the defective LED chip, the method further comprises:
supplementing a further LED chip to a pad-group corresponding to the defective LED chip.

14. The method for mass transfer of claim 1, wherein an adhesive force of the insulating-adhesive column to the display backplane is smaller than an adhesive force of the insulating-adhesive column to the growth substrate.

15. The method for mass transfer of claim 1, wherein a temperature for heating is in a range of 120° C. to 140° C.

16. A light-emitting diode (LED) display device, comprising:
a display backplane; and
a plurality of LED chips, the plurality of LED chips being transferred to the display backplane by:
applying an insulating-adhesive on a growth substrate, wherein the insulating-adhesive applied is between any two adjacent LED chips on the growth substrate;
placing the growth substrate above the display backplane, wherein a distance between the growth substrate and the display backplane after placing is greater than a height of an LED chip;
forming an insulating-adhesive column between the growth substrate and the display backplane by softening the insulating-adhesive through heating, wherein the softened insulating-adhesive subjected to heating is adhered to the display backplane;
separating an LED chip from the growth substrate, to make the separated LED chip fall onto a corresponding pad-group through a channel formed by insulating-adhesive columns around the separated LED chip; and
bonding the fallen LED chip with the corresponding pad-group on the display backplane.

17. The LED display device of claim 16, wherein the insulating-adhesive column has a cross section with narrow ends and wide middle.

18. The LED display device of claim 16, wherein the insulating-adhesive column is spaced apart from any two adjacent LED chips.

19. The LED display device of claim 16, wherein a second groove is defined between any two adjacent pad-groups on the display backplane.

20. A display apparatus, comprising:
a drive circuit; and
a light-emitting diode (LED) display device, electrically connected to the drive circuit, and comprising a display backplane and a plurality of LED chips, the plurality of LED chips being transferred to the display backplane by:
applying an insulating-adhesive on a growth substrate, wherein the insulating-adhesive applied is between any two adjacent LED chips on the growth substrate;
placing the growth substrate above the display backplane, wherein a distance between the growth substrate and the display backplane after placing is greater than a height of an LED chip;
forming an insulating-adhesive column between the growth substrate and the display backplane by softening the insulating-adhesive through heating, wherein the softened insulating-adhesive subjected to heating is adhered to the display backplane;
separating an LED chip from the growth substrate, to make the separated LED chip fall onto a corresponding pad-group through a channel formed by insulating-adhesive columns around the separated LED chip; and
bonding the fallen LED chip with the corresponding pad-group on the display backplane.
